(19) United States
(12) Patent Application Publication
(10) Pub. No.: US 2010/0186398 A1
(43) Pub. Date: Jul. 29, 2010

(54) Thermoelectric facility comprising a thermoelectric generator and means for limiting the temperature on the generator

(76) Inventor: Norbert Huber, Erlangen (DE)

Correspondence Address: STAAS & HALSEY LLP, SUITE 700, 1201 NEW YORK AVENUE, N.W., WASHINGTON, DC, 20005, US

(21) Appl. No.: 12/310,542

(22) PCT Filed: Aug. 22, 2007
(86) PCT No.: PCT/EP2007/058717

§ 371 Date: Feb. 27, 2009

(30) Foreign Application Priority Data
Aug. 31, 2006 (DE) 10 2006 040 855.1

(51) Int. Cl. F01N 5/02; H01L 35/30; F01P 1/06

(52) U.S. Cl. 60/320; 136/205; 123/41.31

(57) ABSTRACT

The thermoelectric facility has a thermoelectric generator and a structure for limiting the temperature thereof. The structure has a flat compartment which is at least substantially filled with an evaporable working medium. The dimensions of the compartment are adapted to those of the thermoelectric generator and the compartment is thermally connected to a heat source or to the thermoelectric generator across a large surface of its opposite surfaces. The temperature-limiting structure also includes a conduit system, connected to the compartment, into which a recirculation cooler is integrated to which a gaseous portion of the working medium can freely rise from the compartment. The working medium should have a boiling point that is at least below a critical temperature above which the thermoelectric generator will be permanently damaged. The thermoelectric facility is especially useful for motor vehicles that are operated by an internal combustion engine.

This application is based on and hereby claims priority to German Application No. 10 2006 040 855.1 filed on Aug. 31, 2006 and PCT Application No. PCT/EP2007/058717 filed on Aug. 22, 2007, the contents of which are hereby incorporated by reference.

### BACKGROUND OF THE INVENTION

The invention relates to a thermoelectrical device having
a) a thermoelectrical generator, a heat source and a heat sink, wherein the thermoelectrical generator is thermally connected on a first side to the heat source and on a second side to the heat sink,
b) a chamber,
   which is thermally connected over a large area to the heat source and to the thermoelectrical generator,
   which is at least largely filled with a working medium which can be vaporized, and
   can circulate in the liquid and gaseous working medium by virtue of a thermosiphon effect, and
c) a structure for temperature limiting on the thermoelectrical generator,
   wherein
   the working medium has a boiling temperature Tₛ which is below a critical temperature above which the thermoelectrical generator is permanently damaged. One such thermoelectrical device is disclosed in U.S. Pat. No. 3,881,962.

Heat can be converted directly to electrical energy using a so-called thermoelectrical generator. A thermoelectrical generator is a component composed of two different materials which are connected to one another, preferably two different or differently doped semiconductors, which produces an electrical voltage on the basis of the Seebeck effect when the junction points of the different materials are at different temperatures.

The Seebeck effect describes the creation of an electrical voltage in an electrical conductor along a temperature gradient, caused by thermodiffusion flows. In order to allow technical use to be made of the Seebeck effect, it is necessary to bring two different electrical conductors with a different electronic heat capacity into contact with one another. As a result of the different electronic heat capacity, the electrons in the two conductors have different energies of motion at the same temperature. If these conductors are brought into contact with one another, then a diffusion flow of relatively high energy electrons will take place in the direction of the conductor with the low-energy electrons until this results in a dynamic equilibrium. If these two different conductors are denoted A and B and are brought into contact in the sequence A-B-A and, furthermore, if the junction A-B is at a temperature T₁ and the junction B-A is at a temperature T₂, then the resultant voltage is dependent only on the difference between the temperatures T₁ and T₂ and the respective Seebeck coefficient of the two conductors A and B. In consequence, a voltage which can be tapped off on a thermoelectrical generator is dependent only on the temperature difference applied to the thermal generator and on the Seebeck coefficients of the materials used.

In principle, a thermoelectrical generator can be constructed analogously to a Peltier element. Identical or similar materials as for the production of Peltier elements, for example bismuth-tellurite or silicon-germanium, can also be used for a thermoelectrical generator.

The use of semiconductor materials allows the efficiency of a thermoelectrical generator for conversion of thermal energy to electrical energy to rise to several percent. Thermoelectrical generators have recently been increasingly used for exhaust gas waste heat, for example in the case of motor vehicles, cogeneration units or refuse incineration installations.

DE 33 14 166 A1 discloses a high-efficiency thermoelectrical system. Starting with a hot fluid flow, for example an exhaust gas flow, thermally conductive tubes which are provided with ribs for better thermal linking are heated at one end. The thermally conductive tubes which are heated by the fluid flow conduct the heat to the thermoelectrical generators which are mounted at the opposite end of the thermally conductive tubes, and act as heat sinks. The thermally conductive tubes are filled with an operating fluid in order to improve their thermal conductivity, which operating fluid is vaporized on the hot part of the thermally conductive tubes and recondenses on the somewhat cooler part, on which the thermoelectrical generators are arranged. The thermoelectrical system disclosed in DE 33 14 166 A1 can be used to achieve particularly effective thermal coupling of thermoelectrical generators, for example to an exhaust gas flow. The disclosed system is particularly suitable for use in the high-temperature range at working temperatures of more than 400° C.

U.S. Pat. No. 4,125,122 A discloses a method and an apparatus for thermoelectrical conversion of heat to electrical energy. The disclosed apparatus is designed as a heat exchanger which operates on the opposing-flow principle. The known apparatus provides two mutually separate circuits in which media circulate for heat transmission. A first medium transports heat from a heat source to a heat sink. At least one first thermally conductive tube makes thermal contact with the hot flow of the first medium; at least one second thermally conductive tube makes thermal contact with the cooler flow of the first medium. In the case of the known apparatus, the thermoelectrical generators are in thermal contact both with one of the hot thermally conductive tubes and with one of the cooler thermally conductive tubes. A second medium circulates within the thermally conductive tubes, in a second circuit, driven by a thermosiphon effect. In that thermally conductive tube which is in thermal contact with the hot flow of the first medium, the second medium which is located within the thermally conductive tube circulates in gaseous form from a hot end, which is in thermal contact with the first medium, of the thermally conductive tube to a cooler end, which is in thermal contact with the thermoelectrical generator. At this end, which is in thermal contact with the thermoelectrical generator, the gaseous second medium condenses and in this way emits the heat condensation to the thermoelectrical generator. The second medium passes back in the liquid phase to the first end of the thermally conductive tube, in order to be vaporized again.

In the case of the apparatus which is disclosed in said U.S. Pat. No. 4,125,122 A, the second medium therefore circulates in the thermally conductive tube which is in thermal contact with the cold side of the thermoelectrical generator, is vaporized at the end of the thermally conductive tube which is in thermal contact with the cold side of the thermoelectrical generator, and condenses on the (even) colder side of the thermally conductive tube which is in contact with the first medium.

Both the thermoelectrical system which is disclosed in DE 33 14 166 A1 and that disclosed in U.S. Pat. No. 4,125,122 A have the aim of thermal coupling of the thermoelectrical generators to a hot operating fluid in a manner which is as effective and free of losses as possible. However, in these systems, there is a risk of their thermoelectrical generators being subjected to excessively high temperatures, and they can therefore be damaged.

A thermoelectrical device having the features mentioned initially is disclosed in said U.S. Pat. No. 3,881,962. In this device, a chamber-like pipeline system is provided and is filled with a working medium which can be vaporized, and the pipeline system runs between a heating area, which can be regarded as a heat source, and a condenser, which can be regarded as a heat sink. In order to provide temperature limiting, in order to prevent damage, on a thermoelectrical module, this model is arranged physically separated from the condenser. Furthermore, a pipeline is additionally connected to the condenser area and leads to a geodetically higher pressure valve by which the pressure of the working medium and thus the thermal flow from the heating area to the condenser can be limited. Temperature limiting such as this on the thermoelectrical module is physically complex.

A further thermoelectrical device having two thermoelectrical generators, a heat source and a heat sink is also disclosed in JP 2003-219 671 A. Two working media with different boiling temperatures are used.

Two operating media are also used in an energy recovery system having a thermoelectrical generator for hybrid cars, as disclosed in WO 2004/092662 A1. One of the operating media is in this case used to cool a heat sink while the other working medium is connected to a heat source in the car.

JP 5-343 751 A discloses a thermoelectrical generator of a solar installation in which water is used as a working medium which can be vaporized. Temperature limiting is achieved on the thermoelectrical generator by the vaporization of the water at its boiling temperature.

A system which is disclosed in EP 1 522 685 A1 for exhaust-gas control of a motor vehicle comprises a thermoelectrical generator having a structure for temperature limiting. In this case, various working media such as oil can be used to transport heat from an exhaust-gas system as a heat source to the thermoelectrical generator. A thermal contact area, which can be varied with the temperature conditions, to the thermoelectrical generator, in particular using a meltable solder material, leads to temperature limiting on the generator.

### SUMMARY

One potential object is to specify a thermoelectrical device having the features mentioned initially, which allows good matching to the respective temperature such that the risk of unacceptable overheating that has been mentioned then does not exist.

The inventor studied the idea of using the latent heat of a phase change for protection of a thermoelectrical generator against overheating. The thermoelectrical device should have a thermoelectrical generator, a heat source and a heat sink, wherein the thermoelectrical generator is thermally connected on a first side to the heat source and on a second side to the heat sink. The thermoelectrical device should furthermore have a chamber which is thermally connected over a large area to the heat source and to the thermoelectrical generator, which is at least largely filled with a working medium which can be vaporized, and can circulate in the liquid and gaseous working medium by virtue of a thermosiphon effect. Furthermore, a structure is intended to be provided for temperature limiting on the thermoelectrical generator. In this case, the working medium should have a boiling temperature Tₛ which is below a critical temperature above which the thermoelectrical generator is permanently damaged.

The structure for temperature limiting on the thermoelectrical generator should comprise the chamber and a pipeline system which is connected thereto and in which a recooler is integrated. In this case:
the chamber should be flat, with mutually opposite surfaces,
the dimensions of the chamber should be matched to those of the thermoelectrical generator,
the chamber should be thermally connected by one of the mutually opposite surfaces over a large area to the heat source and by the other, over a large area to the thermoelectrical generator,
the recooler should be integrated in the pipeline system at a point which is geodetically higher than the chamber,
the pipeline system should be designed such that a gaseous component of the working medium can rise without impairment to the recooler from the chamber in order to be liquefied again,
   and
liquid and gaseous working medium should be able to circulate at least in parts of the chamber and of the pipeline system by virtue of a thermosiphon effect.

The advantages associated with this refinement of the thermoelectrical device are, in particular, that, when the temperature of the heat source rises, the thermoelectrical generator, which is thermally coupled thereto by the liquid-filled chamber, is protected against thermal destruction. When the heat source reaches the boiling temperature of the working medium, then excess thermal energy which would otherwise contribute to loading of the thermoelectrical generator is converted by the phase transition of the working medium. If further heat is supplied, vaporized working medium is liquefied again in the recooler, and excess energy is dissipated in this way. It is particularly advantageous that it is possible to use thermoelectrical generators in the thermoelectrical device which have a working temperature which is below the temperature of the heat source. A further advantage is that any temperature peaks that occur can be coped with when the temperature of the heat source fluctuates.

In many cases, a liquid has a lower thermal conductivity than a solid body. The heat flow originating from the heat source is opposed by the arrangement of a further resistance as described above. This can contribute to additional protection of the thermoelectrical generator.

The thermoelectrical device can also have the following features:
The structure for temperature limiting may thus have a flat second chamber, which has mutually opposite surfaces, whose dimensions can be matched to those of the thermoelectrical generator, which can be connected by one of the mutually opposite surfaces over a large area to the heat source and by the other over a large area to the first chamber, and which can be at least largely filled with a second, meltable working medium. In this case, the second working medium should have a melting temperature T_{L} which is below a critical temperature above which the thermoelectrical generator is permanently damaged.
One particularly advantageous feature of this refinement of the thermoelectrical device is that excess thermal energy which originates from the heat source can be stored as latent heat of the “solid-liquid” phase transition of the second working medium. When the temperature of the heat source changes, this allows the temperature peaks to be coped with and to be stored. The stored thermal energy is passed to the thermoelectrical generator again, in the form of solidification heat, when the temperature of the heat source falls. This allows the temperature difference across the thermoelectric generator to be kept at a desired value in such a way that a power which is as constant as possible can always be demanded from the thermoelectrical generator.
Alternatively, the structure for temperature limiting may have a flat second chamber which has mutually opposite surfaces, whose dimensions can be matched to those of the thermoelectrical generator, which can be connected by one of the mutually opposite surfaces over a large area to the first chamber and by the other over a large area to the thermoelectrical generator, and which can be at least largely filled with a second, meltable working medium. In this case, the second working medium should have a melting temperature T_{L} which is below a critical temperature above which the thermoelectrical generator is permanently damaged. An arrangement of the second chamber such as this means that the heat flow which originates from the heat source first of all passes through the second chamber before it passes through the first chamber, which is filled with a liquid which can be vaporized, in order finally to arrive at the thermoelectrical generator. If the temperature of the heat source rises, when the melting temperature of the second working medium is reached, thermal energy is stored by virtue of the “solid-liquid” phase transition of the second working medium which is located in the second chamber. If the temperature rises further, or if a high temperature remains constant, with an ongoing heat flow, thermal energy is converted by the “liquid-gaseous” phase transition of the first medium. Finally, excess heat is dissipated via the recooler by condensation of the gaseous first working medium on the recooler. The refinement described above is particularly advantageous since excess heat is dissipated via the recooler only in the situation in which the heat store is saturated. This allows the overall efficiency of the thermoelectrical device to be improved, while at the same time ensuring effective protection for the thermoelectrical generator against overheating.
The second working medium may have a melting temperature which corresponds essentially to a preferred working temperature of the thermoelectrical generator, in which case the working temperature may be below the critical temperature above which the thermoelectrical generator is permanently damaged. According to the described exemplary embodiment, the thermoelectrical generator can be kept at an optimum working temperature, in a particularly advantageous manner, by melting and solidification of the second working medium.
However, the second working medium may also have a melting temperature which corresponds essentially to a preferred working temperature of the thermoelectrical generator, in which case the working temperature may be below the boiling temperature of the first working medium. The described choice of the melting temperature of the second working medium and the boiling temperature of the first working medium allows the thermoelectrical generator to be kept at a desired working temperature. When the temperature of the heat source rises above the preferred working temperature of the thermoelectrical generator, the excess heat is first of all changed to latent heat by the phase transition of the second medium from solid to liquid. Only in the situation in which the temperature of the heat source rises further after exhaustion of the heat store is the boiling temperature of the first working medium reached, and excess heat is dissipated. When the temperature of the heat source falls, the solidification heat of the second medium can be emitted to the thermoelectrical generator.
The second working medium may have a lower thermal conductivity in the liquid state than in the solid state. Every physical component has a specific thermal resistance. If the thermal resistance of the liquid phase of a material is higher than the thermal resistance of the solid phase, then the thermal resistance of the corresponding material rises when the melting temperature is exceeded. If a material such as this is used as the second working medium in a thermoelectrical device, then the thermoelectrical generator can be protected better by a rise in the thermal resistance of the second working medium.
The recooler may have a further thermoelectrical generator which is thermally connected on a first side to a third chamber, which is connected to the pipeline system, and on a second side to a heat sink. A refinementof the recooler such as this also allows the heat dissipated via the recooler to additionally be used to generate electrical energy. This makes it possible to improve the efficiency of the thermoelectrical device.
The heat source can be thermally connected at least to parts of an exhaust-gas system of an internal combustion engine, or may be formed by at least parts of the exhaust-gas system. The exhaust-gas heat of an internal combustion engine such as this can be made use of by using a thermoelectrical generator which is thermally coupled to the exhaust-gas system of an internal combustion engine.
The heat sink may be thermally connected at least with parts of a cooling system of an internal combustion engine, or may be formed by at least parts of the cooling system. A heat source and a heat sink are required in order to maintain a temperature difference, across a thermoelectrical generator, for operation of that thermoelectrical generator. Typically, an internal combustion engine has a cooling system and therefore in this way allows a heat sink to be provided in a simple and effective manner for the thermoelectrical generator.
The heat sink can be thermally connected to a surface which is to be cooled by an air flow. Since a surface which is to be cooled by an air flow can be used as a heat sink for a thermoelectrical generator, a simple, robust and low-cost component can be specified as a heat sink for the thermoelectrical generator.
The recooler may be thermally connected to at least parts of a cooling system of an internal combustion engine, or may be formed by at least parts of the cooling system. The thermal coupling of the recooler to the cooling system of an internal combustion engine ensures similar, or in some cases the same, advantages as the thermal coupling of a heat sink to the cooling system of an internal combustion engine.
The internal combustion engine may be part of a motor vehicle. Now motor vehicles require ever greater amounts of electrical energy in order to operate various electronic devices. The use of the exhaust-gas heat from the internal combustion engine of the motor vehicle reduces the primary energy demand in the motor vehicle for carrying the required electrical energy.
The first working medium may be an oil, preferably an engine oil, with a boiling temperature of between 100° C. and 500° C., preferably with a boiling temperature of between 200° C. and 300° C., at a pressure of 2 to 5 bar. The stated temperature ranges are particularly suitable for operation of a thermoelectrical generator. The cooling water in a cooling system of an internal combustion engine typically has a maximum temperature of about 100° C. The cooling water can be used as a heat sink for operation of a thermoelectrical generator. In order to ensure an effective energy yield as a result of the temperature difference across the thermoelectrical generator, the hot side of the thermoelectrical generator should be at a temperature of more than about 200° C. The maximum load capacity of typical thermoelectrical generators which are commercially widely available is about 300° C. Thermoelectrical generators, which are designed specifically for high-temperature applications, have a maximum load capacity of about 500° C. Since the boiling temperature of the first working medium defines the maximum temperature allowed by the structure for temperature limiting, a boiling point of the working medium in the stated temperature ranges is particularly advantageous.
The second working medium may be a solder which, in particular, contains lead, tellurium or bismuth at least as an alloy partner. A solder which contains one or more of the abovementioned elements or is formed by them provides the physical characteristics desired for the second working medium, and has also been proven in technical use.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 shows the schematic design of a thermoelectrical device with a structure for temperature limiting,

FIGS. 2 and 3 show the schematic design of a thermoelectrical device in which the structure for temperature limiting additionally has a second chamber, which is filled with a second working medium,

FIG. 4 shows a schematic illustration of the temperature of a thermoelectrical generator of a device, as a function of time,

FIG. 5 shows the schematic design of a thermoelectrical device in which the heat source is connected to parts of the exhaust-gas system of an internal combustion engine,

FIG. 6 shows the schematic design of a thermoelectrical device in which the heat source is connected to parts of the exhaust-gas system and the heat sink and the recooler are connected to parts of the cooling system of the internal combustion engine, and

FIG. 7 shows the schematic design of a thermoelectrical device in which the recooler has a further thermoelectrical generator.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

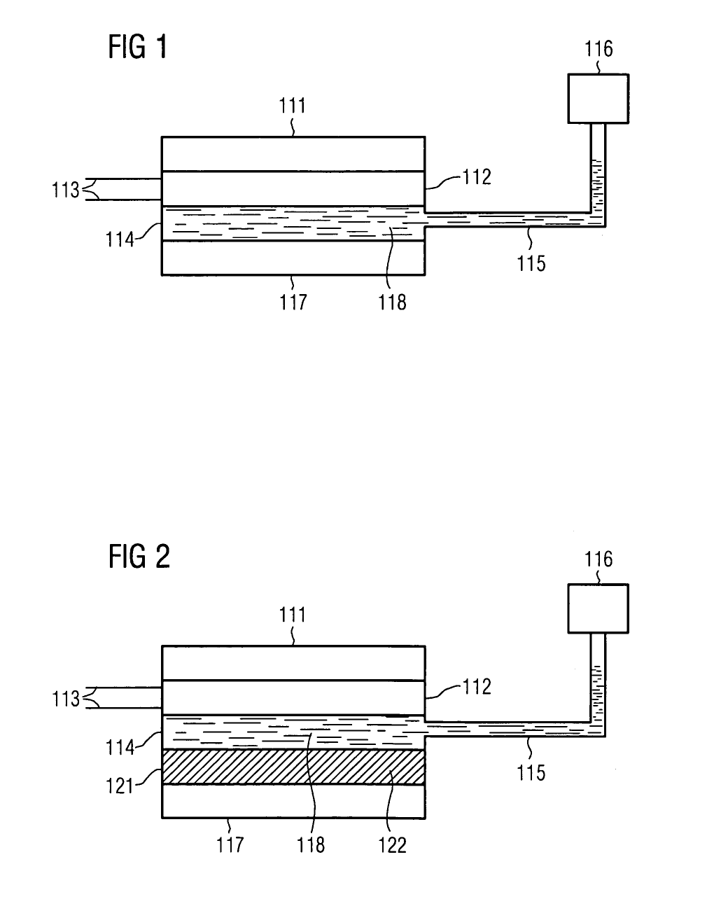

FIG. 1 shows the schematic design of a thermoelectrical device according to one preferred exemplary embodiment. The thermoelectrical device, in particular in the form of one of its special refinements, can be used particularly advantageously in a motor vehicle with an internal combustion engine, wherein there is a gaseous working medium in the first chamber when the internal combustion engine is on full load or is subject to a peak load. In a particularly advantageous manner, the use of the abovementioned thermoelectrical device makes it possible to protect the thermoelectrical generator against overheating when the internal combustion engine is on full load or is subject to a peak load, for example when the motor vehicle is going uphill. In the device, a thermoelectrical generator 112 is thermally connected on one side over a large area to a heat sink 111. On the opposite side, the thermoelectrical generator 112 is connected to a chamber 114 at least the majority of which is filled with a liquid 118, which can be vaporized, as a first working medium. The chamber 114 which is filled with the liquid 118 which can be vaporized is in turn thermally connected over a large area to a heat source 117. The thermal connection between the abovementioned components can preferably be provided by a mechanical connection, with an interlock. In this case, the above-mentioned components can be connected to one another, for example, by a solder. The thermal connection between the components can additionally be improved by the use of a thermally conductive paste. When there is a temperature difference across the thermoelectrical generator 112, it generates electrical energy. The thermoelectrical generator can be electrically connected at the contacts 113 to a load, store etc.

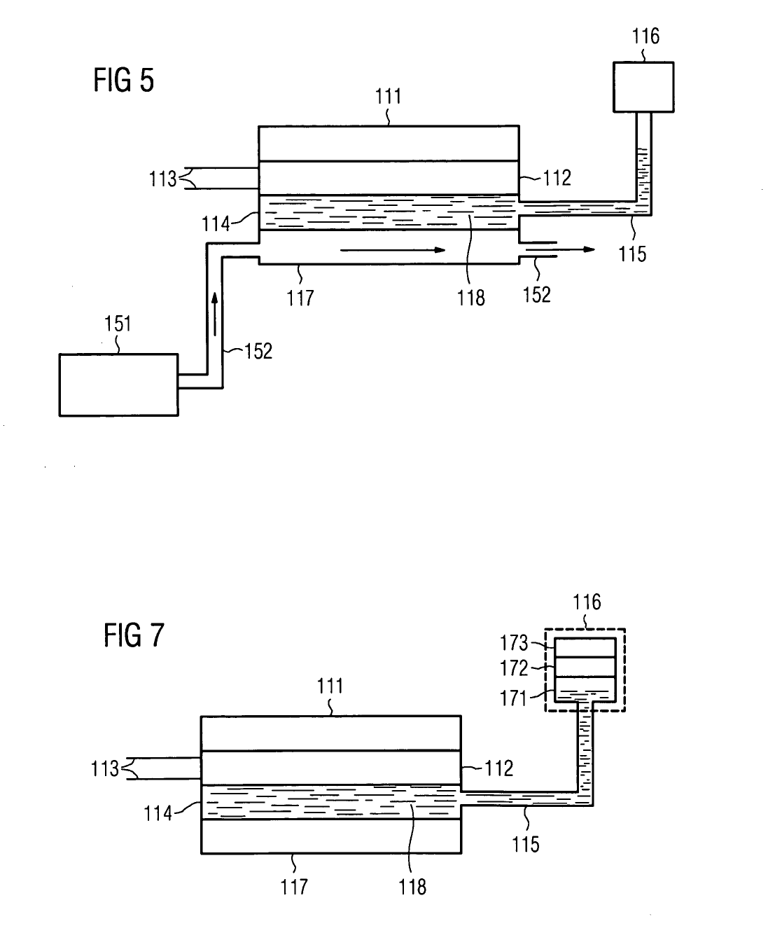

Like virtually all electronic components, a thermoelectrical generator 112 has a maximum thermal load capacity. This means that a predetermined critical temperature 141 exists (cf. FIG. 4) above which the thermoelectrical generator 112 can be damaged if it is subjected to this predetermined critical temperature 141, or to a higher temperature, for too long. A thermoelectrical generator 112 is preferably formed from a plurality of semiconductor elements which are soldered to one another. The thermoelectrical generator 112 can also be destroyed by a thermal load on the thermoelectrical generator 112 which is higher than the melting temperature of the solvent that is used for connection of the semiconductor elements.

In order to protect the thermoelectrical generator 112 against thermal damage, the chamber 114 is connected to a pipeline system 115 in which a recooler 116 is integrated. As is indicated in FIG. 1, the pipeline system 115 may be connected at one end to the chamber 114. In the same way, the pipeline system may comprise further parts which are connected to the chamber 114 at further points. In this way, the pipeline system may have parts which, for example, are connected to two opposite sides of the chamber 114. A plurality of parts of the pipeline system 114 can likewise be connected to a common side of the chamber. The working medium 118 which is located in the chamber 114 can preferably have a boiling temperature Tₛ which corresponds to a preferred working temperature 143 (cf. FIG. 4) of the thermoelectrical generator 112. The boiling temperature Tₛ should preferably be below the critical temperature 141 above which the thermoelectrical generator 112 is permanently damaged. Further details will be explained in conjunction with FIG. 4.

When the temperature of the heat source 117 rises above the boiling temperature of the working medium Tₛ, then at least parts of the working medium 118 are vaporized in the chamber 114. Gaseous working medium 118 can rise without any impediment from the chamber 114 via the pipeline system 115 to the recooler 116 which is integrated in the pipeline system 115. For this purpose, the recooler 116 is located at a geodetically higher point than the chamber 114. Gaseous working medium 116 can be liquefied again by the recooler 116, and can then be passed back into the chamber 114 by the influence of the force of gravity.

Liquid and gaseous working medium 118 can circulate in at least parts of the chamber 114 and of the pipeline system 115, by virtue of a thermosiphon effect.

Thermal energy originating from the heat source 117 can be carried away to the recooler 116 by the working medium 118 which can be vaporized in a specific manner. In this case, the thermoelectrical generator 112 can be protected against thermal overheating.

Thermal peak loads can originate from the heat source 117 for a limited time or else continuously over time. If the heat source 117 is continuously at a temperature which is above the preferred working temperature 142 of the thermoelectrical generator 112 and is also above the building temperature Tₛ of the working medium 118, excess heat is carried away continuously to the recooler 116, by the boiling working medium 118. If the temperature of the heat source 117 rises for a limited time, working medium 118 can be changed temporarily to the gaseous phase and can then liquefy again on relatively cool parts, for example those of the thermoelectrical generator 112, or on parts of the pipeline system 115, even without this being influenced by the recooler 116.

The preferred exemplary embodiment of a thermoelectrical device as illustrated in FIG. 1 is not restricted to a flat arrangement, as illustrated in FIG. 1, of a heat source 117, chamber 114, thermoelectrical generator 112 and heat sink 111. Just as advantageously, a multi-layer structure may be produced, which has a plurality of heat sources 117, heat sinks 111 and a plurality of chambers 114, which are filled with a working medium 118, and thermoelectrical generators 112. The thermoelectrical arrangement may likewise advantageously be in a curved form.

FIG. 2 shows a further preferred exemplary embodiment of a thermoelectrical device in which the arrangement, known in a general form from FIG. 1, has had added to it a second chamber 121 which is filled with a meltable second working medium 122. The second working medium 122 can preferably have a melting temperature T_{L} which is below the boiling temperature Tₛ of the first working medium 118. Further details will be given in conjunction with FIG. 4. If the temperature of the heat source 117 rises above the melting temperature T_{L} of the second working medium 122, then the thermal energy originating from the heat source 117 is used to melt the second working medium 122. Only when the second working medium 122 has been completely liquefied, and the heat store 121 has been effectively exhausted, does the temperature on the thermoelectrical generator 112 rise above the melting temperature T_{L} of the second working medium 122. If the temperature of the heat source 117 rises further, the heat flow is carried away to the recooler 116 through the working medium 118 boiling in the chamber 114.

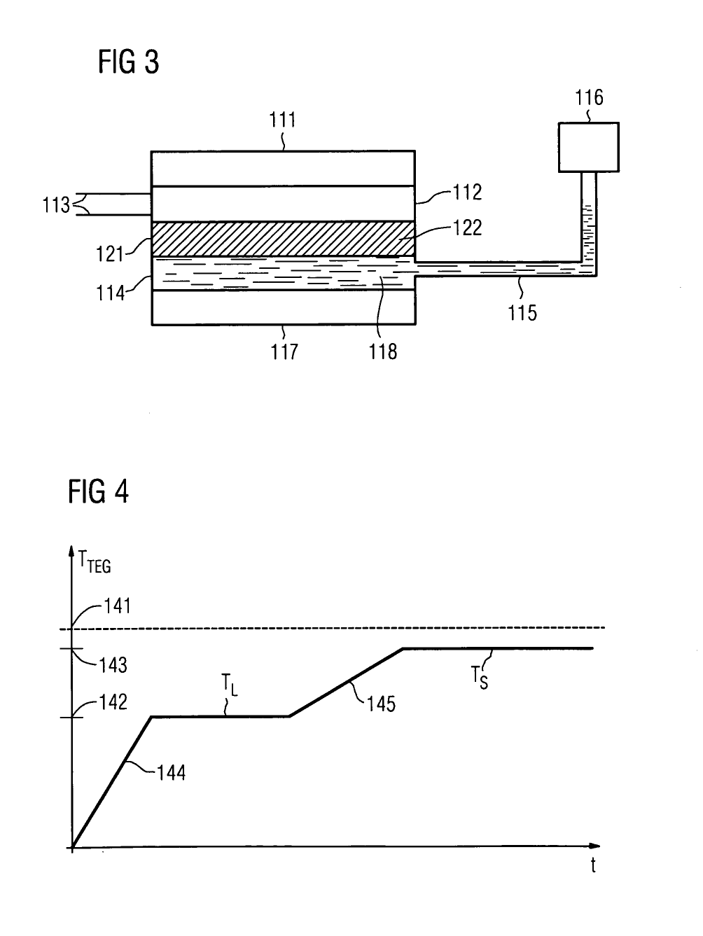

FIG. 3 shows a further preferred exemplary embodiment in which the second chamber 121, which is filled with a second working medium 122, is arranged between the chamber 114, which is filled with the first working medium 118, and the thermoelectrical generator 112. The melting temperature T_{L} of the second medium can preferably be below the boiling temperature Tₛ of the first medium 118. The thermal conductivity of a liquid is typically less than the thermal conductivity of a solid body. The heat flow originating from the heat source 117 is thus initially counteracted on its way to the thermoelectrical generator 112 by a thermal resistance in the form of the first chamber 114. If a very hot heat source 117 is used to operate the thermoelectrical generator 112, it may be advantageous to use a thermal resistance to reduce the high temperature of the heat source.

FIG. 4 shows a schematic illustration of the temperature profile T_{TEG} on the hot side of the thermoelectrical generator 112, as a function of time t. It is assumed that the heat source 117 is at a constantly high temperature, which should preferably be above the critical temperature 141 above which the thermoelectrical generator 112 is permanently damaged. The curve illustrated in FIG. 4 is preferably based on an exemplary embodiment as shown in FIG. 2.

If the temperature of the heat source 117 rises, the temperature of the thermoelectrical generator T_{TEG} initially follows that part of the graph annotated 144. If the temperature of the thermoelectrical generator 112 reaches the melting temperature T_{L} of the second working medium, the temperature of the thermoelectrical generator T_{TEG} will also initially not rise any further, even if further heat is supplied. The position on the temperature axis of the resultant plateau is governed by the melting temperature T_{L} of the second medium 122, and the mass or heat capacity of the second medium 122 governs the time over which the plateau extends. The melting temperature of the second working medium 122 preferably corresponds essentially to a preferred working temperature 142 of the thermoelectrical generator 112.

The temperature T_{TEG} of the thermoelectrical generator 112 will not rise any further until the second medium 122 has been melted completely. Because of the lower thermal conductivity of the liquid phase of the second working medium 122, the temperature rises, as indicated by the part of the curve annotated 145 in FIG. 4, with a flatter gradient than before in the part of the graph annotated 144. If further thermal energy is produced by the heat source 117, the temperature of the thermoelectrical generator 112 rises to the boiling temperature Tₛ of the first working medium 118, which preferably corresponds essentially to the maximum permissible working temperature 143 of the thermoelectrical generator 112. Gaseous working medium 118 can rise to the recooler 116, where it is liquefied again. This allows excess thermal energy to be carried away to the recooler 116 by the gaseous second medium 118.

Even if the temperature of the heat source 117 rises further and/or a heat flow continues at a temperature level above the critical temperature 141, a further rise in the temperature T_{TEG} of the thermoelectrical generator 112 can be avoided by the vaporization and recooling of the first working medium 118. This means that the thermal destruction threshold 141 of the thermoelectrical generator 112 will not be reached, and that it is protected against thermal overheating.

FIG. 5 shows a further preferred exemplary embodiment of a thermoelectrical device. The design illustrated in FIG. 5 is a design that is generally known from FIG. 1 that has been added to such that the heat source 117 is connected to parts of the exhaust-gas system 152 of an internal combustion engine 151. The chamber 114 can preferably be connected to the exhaust-gas system 152 of an internal combustion engine by the use of further measures, for example corrosion-protective measures.

The preferred exemplary embodiment illustrated in FIG. 5 is not restricted to the embodiment illustrated in the figure. The exhaust-gas flow can likewise be passed through an exhaust-gas guide system 152 which branches. In this way, the hot exhaust gas from the internal combustion engine 151 can be brought into thermal contact with a multiplicity of thermoelectrical generators 112. Furthermore, the thermoelectrical generators may be arranged in a structure with a periodic design. For example, a first chamber 114 and the associated thermoelectrical generator 112 may in each case be arranged on the opposite sides of an exhaust-gas channel. A cooling channel or a cooling lug can be arranged on each of the cold sides of the thermoelectrical generators 114, and these are used as heat sinks 111. A further thermoelectrical generator 112 can also in each case be arranged with its cold side on this cooling channel. This makes it possible to design a periodic structure comprising exhaust-gas channels, thermoelectrical generators 112 with the structure for temperature limiting, and cooling channels.

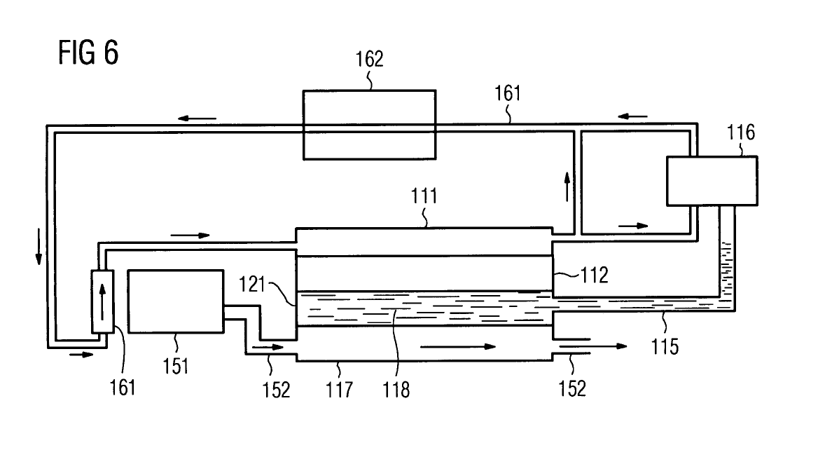

FIG. 6 shows a further preferred exemplary embodiment of a thermoelectrical device in which, in comparison to the exemplary embodiment illustrated in FIG. 5, the heat sink 111 is coupled to the cooling system 161 of an internal combustion engine 151. The cooling system 161 may be a generally known cooling system, which is normally operated with cooling water, for an internal combustion engine 151, or else, for example, the oil cooling system of an internal combustion engine 151. By way of example, commercially available lubricating oil or cooling oil can be used as the first working medium 118. It is likewise possible to use an oil which has been specifically modified for use in a thermoelectrical device with the structure for temperature limiting.

The cooling water which is used to cool the internal combustion engine 151 can preferably be used to control the temperature of the heat sink 111, that is to say it can be thermally connected to it. Furthermore, the recooler 116 can likewise be integrated in the cooling system 161 of the internal combustion engine 151. This makes it possible also to ensure that the recooler 116 is cooled, and that this can be kept at a temperature as required for the gaseous first working medium 118 to be liquefied again. A surface 162 which is to be cooled by an airflow can likewise be thermally connected to the heat sink 111. This refinement can be used in particular when the thermoelectrical device is used in a motor vehicle. In this case, for example, the surface 162 can be cooled by the wind of motion.

FIG. 7 shows a further preferred exemplary embodiment of a thermoelectrical device. In comparison to the exemplary embodiment illustrated in FIG. 1, the recooler 116 is in the form of a further thermoelectrical device. For this purpose, the pipeline system 115 is connected to a further, third chamber 171. This third chamber 171 may be at least partially filled with the first working medium 118. The third chamber 171 is at least thermally, and preferably also mechanically, connected to the hot side of a further thermoelectrical generator 172. The cold side of the thermoelectrical generator 172 is connected to a heat sink 173. The integration of a further thermoelectrical generator 172 in the recooler 116 makes it possible to additionally use the thermal energy carried away via the recooler 116 to generate electrical energy. This makes it possible to improve the efficiency of the overall thermoelectrical device. Furthermore, the recooler 116 can also be designed such that, rather than using a single further thermoelectrical generator 172, a cascade is used comprising a plurality of thermoelectrical generators 172 for recooling of the first working medium 118. The cascade comprising a plurality of thermoelectrical generators 172 may in this context be created by a thermal parallel connection or else by a thermal series connection. In this context, thermal parallel connection means thermal coupling of a plurality of thermoelectrical generators 172 whose hot side is connected to a common heat source, for example the third chamber 171.

In the abovementioned context, thermal series connection means thermal coupling of a plurality of thermoelectrical generators 172, in which the hot side of each thermoelectrical generator 172 is connected to the cold side of a further thermoelectrical generator 172.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-16. (canceled)

17. A thermoelectric device comprising:
a thermoelectric generator having opposing first and second sides;
a heat source thermally connected to the first side of the thermoelectric generator;
a heat sink thermally connected to the second side of the thermoelectric generator; and
a temperature limiting structure comprising:
a first chamber having substantially flat first and second mutually opposite surfaces whose dimensions are substantially matched to those of the thermoelectric generator, the first mutually opposite surface being thermally connected to the heat source, the second mutually opposite surface being thermally connected to the thermoelectric generator, the first chamber being substantially filled with a first working medium, which can be vaporized, the first working medium having a boiling temperature which is below a critical temperature above which the thermoelectric generator is permanently damaged;
a pipeline system which is connected to the first chamber; and
a recooler integrated in the pipeline system at a point which is geodetically higher than the first chamber, the pipeline system being designed such that a gaseous component of the first working medium can rise to the recooler without impairment from the first chamber, in order to be liquefied, the pipeline system being designed such that a thermosiphon effect circulates liquid and gaseous first working medium at least in parts of the first chamber and the pipeline system.

18. The thermoelectric device as claimed in claim 17, wherein
the structure for temperature limiting further comprises a substantially flat second chamber which has first and second mutually opposite surfaces whose dimensions are matched to those of the thermoelectric generator, the first mutually opposite surface of the second chamber being connected to the heat source, the second mutually opposite surface of the second chamber being connected to the first chamber, the second chamber being at least partially filled with a meltable second working medium having a melting temperature which is below the critical temperature above which the thermoelectric generator is permanently damaged.

19. The thermoelectric device as claimed in claim 17, wherein
the structure for temperature limiting further comprises a substantially flat second chamber which has first and second mutually opposite surfaces whose dimensions are matched to those of the thermoelectric generator, the first mutually opposite surface of the second chamber being connected to the first chamber, the second mutually opposite surface of the second chamber being connected to the thermoelectric generator, the second chamber being at least partially filled with a meltable second working medium having a melting temperature which is below the critical temperature above which the thermoelectric generator is permanently damaged.

20. The thermoelectric device as claimed in claim 18, wherein
the second working medium has a melting temperature which corresponds essentially to a preferred working temperature of the thermoelectric generator, and
the preferred working temperature is below the critical temperature above which the thermoelectric generator is permanently damaged.

21. The thermoelectric device as claimed in claim 18, wherein
the second working medium has a melting temperature which corresponds essentially to a preferred working temperature of the thermoelectric generator, and
the preferred working temperature is below the boiling temperature of the first working medium.

22. The device as claimed in claim 18, wherein the second working medium has a lower thermal conductivity in a liquid state than in a solid state.

23. The thermoelectric device as claimed in claim 17, wherein
the recooler comprises a recooler thermoelectric generator, a recooler chamber connected to the pipeline system and a recooler heat sink, the recooler thermoelectric generator having first and second sides, the first side of the recooler thermoelectric generator being thermally connected to the recooler chamber, the second side of the recooler thermoelectric generator being connected to the recooler heat sink.

24. The thermoelectric device as claimed in claim 17, wherein the heat source is thermally connected to parts of an exhaust-gas system of an internal combustion engine, or is formed by parts of the exhaust-gas system.

25. The thermoelectric device as claimed in claim 17, wherein the heat sink is thermally connected to parts of a cooling system of an internal combustion engine, or is formed by parts of the cooling system.

26. The thermoelectric device as claimed in claim 17, wherein the heat sink is thermally connected to a surface cooled by an air flow.

27. The thermoelectric device as claimed in claim 17, wherein the recooler is thermally connected to parts of a cooling system of an internal combustion engine, or is formed by parts of the cooling system.

28. The thermoelectric device as claimed in claim 17, wherein the internal combustion engine is part of a motor vehicle.

29. The thermoelectric device as claimed in claim 17, wherein the first working medium is an oil with a boiling temperature of between 100° C. and 500° C. at a pressure of between 2 bar and 5 bar.

30. The thermoelectric device as claimed in claim 29, wherein
the oil is an engine oil,
the engine oil has a boiling temperature of between 200° C. and 300° C. at a pressure of between 2 bar and 5 bar.

31. The thermoelectric device as claimed in claim 18, wherein the second working medium is a solder.

32. The thermoelectric device as claimed in claim 31, wherein the solder contains at least one of lead, tellurium, bismuth and alloys thereof.

33. The thermoelectric device as claimed in claim 19, wherein
the second working medium has a melting temperature which corresponds essentially to a preferred working temperature of the thermoelectric generator, and
the preferred working temperature is below the critical temperature above which the thermoelectric generator is permanently damaged.

34. The thermoelectric device as claimed in claim 19, wherein
the second working medium has a melting temperature which corresponds essentially to a preferred working temperature of the thermoelectric generator, and
the preferred working temperature is below the boiling temperature of the first working medium.

35. The device as claimed in claim 19, wherein the second working medium has a lower thermal conductivity in a liquid state than in a solid state.
